(19) United States
(12) Patent Application Publication
(10) Pub. No.: US 2002/0199139 A1
(43) Pub. Date: Dec. 26, 2002

(54) Test configuration for a parallel functional testing of semiconductor memory modules and test method

(76) Inventors: Jean-Marc Dortu, Munchen (DE); Robert Feurle, Neubiberg (DE); Andreas Tauber, Unterschleissheim (DE); Paul Schmolz, Munchen (DE)

Correspondence Address: LERNER AND GREENBERG, P.A., Post Office Box 2480, Hollywood, FL, 33022-2480, US

(21) Appl. No.: 10/177,887

(22) Filed: Jun. 20, 2002

(30) Foreign Application Priority Data
Jun. 20, 2001 (DE) 101 29 771.8

(51) Int. Cl. G11C 29/00

(52) U.S. Cl. 714/718

(57) ABSTRACT

A test configuration for a parallel functional testing of semiconductor memory modules includes a test unit which provides a test sequence, feeds it to a module to be tested, and receives response signals generated by the module to be tested after the test sequence has been run through. A test logic circuit, which is connected to the test unit, receives the test sequence and is disposed on the module to be tested. The test unit is connected to the test logic circuit via a narrow interface for a bidirectional communication. For this purpose, the module to be tested has ports for connecting the interface. Only one of the ports serves for outputting of data to be read out from the module. This allows testing a large number of memory modules in parallel.

### BACKGROUND OF THE INVENTION

### FIELD OF THE INVENTION

The invention relates to a method of performing a functional testing of semiconductor memories. The invention relates, in particular, to a test configuration for a parallel functional testing of semiconductor memory modules, in particular of DRAM (Dynamic Random Access Memory) modules.

Integrated semiconductor memories are tested prior to being shipped to customers. Manufacturers use costly memory test systems with which the functional capability of the memory chips is checked with test programs. In this case, signals with precisely defined voltage levels are applied at exactly defined instants to the semiconductor memories to be tested. The response signals generated by the semiconductor memory are read into the test unit and compared with expected signal values.

Due to the high frequencies at which the memory modules operate nowadays, the specification of the chips requires a high accuracy of the signals. Thus, signal specifications in the range of 400 picoseconds are already customary nowadays for example in the case of DDR (Double Data Rate) memories. The production and memory test systems used therefore have to satisfy very stringent technical requirements, which leads to correspondingly high production and test costs. In the case of very high frequency memory modules, the test costs already amount to as much as 30% of the total manufacturing costs.

### SUMMARY OF THE INVENTION

It is accordingly an object of the invention to provide a test configuration which overcomes the above-mentioned disadvantages of the heretofore-known test configurations of this general type and which allows the testing of semiconductor memories with reduced test costs.

For this reason, it is desirable, inter alia, to be able to test as many memory modules as possible in parallel.

With the foregoing and other objects in view there is provided, in accordance with the invention, a test configuration for a parallel functional testing of semiconductor memory modules, including:

a test unit for providing a test sequence;

an interface;

a semiconductor memory module to be tested;

a test logic circuit connected to the test unit via the interface for a bidirectional communication, the test logic circuit being disposed on the semiconductor memory module and receiving the test sequence;

the test unit feeding the test sequence to the semiconductor memory module and the test unit receiving response signals generated by the semiconductor memory module after the test sequence has been run through and the test unit evaluating the response signals; and

the semiconductor memory module having ports for connecting the interface, only one of the ports serving for outputting of data to be read out from the semiconductor memory module.

In other words, a test configuration for a parallel functional testing of semiconductor memory modules, in particular of DRAM modules, includes a test unit, which prescribes a test sequence, feeds it to a module to be tested, and receives, for evaluation, response signals generated by the module to be tested after the test sequence has been run through, the test configuration further includes a test logic circuit, which is connected to the test unit, receives the prescribed test sequence and is disposed on the module to be tested, wherein the test unit is connected to the test logic circuit via an interface for bidirectional communication and the module to be tested has ports for the connection of the interface, only one of the ports serving for outputting of data to be read out from the module.

According to the invention, the test unit is connected to the test logic circuit via a narrow interface for bidirectional communication. For this purpose, the module to be tested has ports for the connection of the interface, only one of the ports serving for the outputting of data to be read out from the module.

The invention is thus based on the concept of transmitting the test sequence information via a narrow interface or slim interface instead of the customarily used wide interface with a plurality of data output ports or pins and a special memory test unit, and of thus obtaining a large gain in parallelism in conjunction with tolerable losses in the transmission time. Since the time reference for the test pass does not have to be transmitted with the interface from the test unit, a slow transmission of the test sequence and a fast execution of the test sequence on the module to be tested are not mutually exclusive.

In a preferred embodiment, the narrow interface is formed by a serial interface. This allows to increase the test parallelism enormously. By contrast, the longer transmission time for the test sequences is only of secondary importance. However, an interface having a width of a plurality of bits also lies within the scope of the invention as long as it enables a gain in parallelism.

Preferably, the module to be tested has at most two ports for the connection of the interface, one of the ports serving for the inputting and outputting of data of the module and for the inputting of commands, and the other of the ports serving for the feeding-in of a clock signal.

In a further advantageous embodiment, the module to be tested has at most three ports for the connection of the interface, a first port serving for the inputting and outputting of data of the module, a second port serving for the inputting of commands and a third port serving for the feeding-in of a clock signal.

In a further advantageous embodiment, the module to be tested has at most four ports for the connection of the interface, a first port serving for the inputting of data, a second port serving for the outputting of data of the module, a third port serving for the inputting of commands and a fourth port serving for the feeding-in of a clock signal.

According to another feature of the invention, the module to be tested has, in each case, an additional port for the feeding-in of a further clock signal. An interface having a width of at most 5 bits is thus obtained.

Preferably, the test configuration includes a time reference device arranged outside the test unit and serving for prescribing a time reference to the module to be tested. In that case, the clock signal does not have to be transmitted via the interface from the test unit, which makes it possible to use a slower but narrower interface.

However, it is also within the scope of the invention for the test unit to have a time reference device for prescribing a time reference to the module to be tested.

A standardized interface, for example according to the JTAG (Joint Test Action Group) standard from the logic test area, is advantageously used for the narrow interface.

Through the use of the invention, instead of expensive high-speed memory testers, considerably more cost-effective high-speed logic testers can then be employed for the functional testing of semiconductor memories.

During operation, the test unit prescribes a test sequence which is fed via the narrow interface to the module to be tested, where the test sequence is run through and the response signals generated by the module to be tested are subsequently fed via the narrow interface to the test unit for evaluation. Preferably, a time reference is prescribed for the module to be tested, independently of the test unit.

With the objects of the invention in view there is also provided, a method for a parallel functional testing of semiconductor memory modules, the method includes the steps of:

providing a test unit connected to a test logic circuit via an interface for bidirectional communication and providing a semiconductor memory module having ports for providing a connection to the interface such that only one of the ports serves for outputting of data to be read out from the semiconductor memory module;

providing a test sequence with the test unit and feeding the test sequence via the interface to the semiconductor memory module to be tested;

running the test sequence on the semiconductor memory module to be tested; and

feeding response signals generated by the semiconductor memory module to be tested via the interface to the test unit after the test sequence has been run through and evaluating the response signals.

In other words, a method for a parallel functional testing of semiconductor memory modules in a test configuration, in which a test sequence is prescribed by the test unit and is fed via the interface to the module to be tested, the test sequence is run through on the module to be tested, and, after the test sequence has been run through, the response signals generated by the module to be tested are fed via the interface to the test unit for evaluation.

Another mode of the method according to the invention includes providing a time reference for the semiconductor memory module to be tested independently of the test unit.

Another mode of the method according to the invention includes feeding the test sequence to the semiconductor memory module to be tested at a relatively lower transmission rate, and carrying out the test sequence on the semiconductor memory module to be tested at a relatively higher execution speed.

Other features which are considered as characteristic for the invention are set forth in the appended claims.

Although the invention is illustrated and described herein as embodied in a test configuration for the parallel functional testing of semiconductor memory modules and a corresponding test method, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic illustration of an exemplary embodiment of a test configuration according to the invention; and

FIGS. 2 and 3 are schematic illustrations of exemplary embodiments of an interface in a test configuration according to the invention.

### DESCRIPTION OF THE PREFERRED EMBODIMENTS

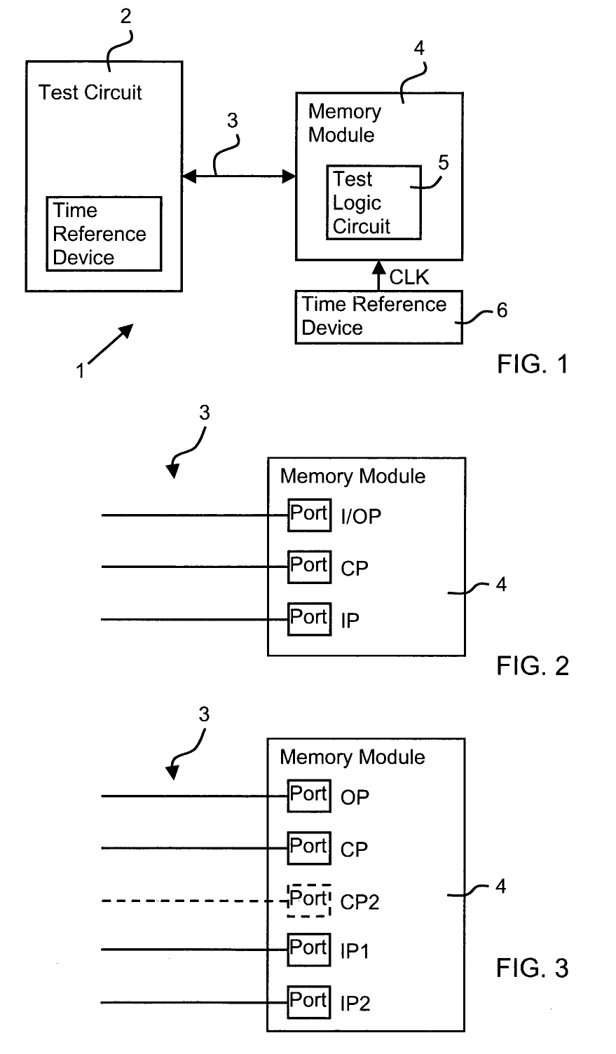

Referring now to the figures of the drawings in detail and first, particularly, to FIG. 1 thereof, there is shown a test configuration 1 including a test unit 2, which communicates bidirectionally via a serial interface 3 with a memory module 4 to be tested. In this case, the memory module 4 to be tested may be, for example, a C10DD0 core with a test controller or an RLDRAM (Reduced Latency DRAM) memory module with a JTAG interface. The test unit 2 communicates a freely programmable or field-programmable test sequence, which may be arbitrarily long or short, to the memory module 4, where the test sequence is loaded by an on-chip test logic 5, for example a BIST (Built-In Self-Test) circuit or a so-called RetPat circuit.

A time reference circuit 6 disposed with the memory module 4 on the board supplies a clock signal CLK to the module 4. Despite slow transmission of the test sequence via the serial interface 3, the sequence can thus be executed at the fast speed of the clock circuit 6. After the test sequence has been run through, the test results are transmitted via the interface 3 to the test unit 2, where they are evaluated in a customary manner.

With the use of a serial interface 3, the memory module 4 occupies only one channel of the test unit 2 during the functional testing. The parallelism of the test can thus be hugely increased compared with the use of a conventional, wide interface.

FIG. 2 shows a diagrammatic illustration of a first exemplary embodiment of an interface in a test configuration according to the invention. The module to be tested has ports for the connection of the interface 3, only port I/OP serving for the outputting of data to be read out from the module.

In this case, the module to be tested has three ports for the connection of the interface 3, a first port I/OP serving for the inputting and outputting of data of the module, a second port IP serving for the inputting of commands and a third port CP serving for the feeding-in of a clock signal. In the case where the port IP is omitted, the module to be tested has two ports for the connection of the interface 3, the port I/OP then serving for the inputting and outputting of data of the module and for the inputting of commands.

In accordance with FIG. 3, the module to be tested has four ports for the connection of the interface 3. A port IP1 serves for the inputting of data, a port OP serves for the outputting of data of the module, a port IP2 serves for the inputting of commands and a port CP serves for feeding in a clock signal.

Furthermore, the module to be tested has an optional, additional port CP2 for feeding in a further clock signal (for example a differential clock signal), which can also be supplemented in the exemplary embodiments explained with reference to FIG. 2. An interface having a width of at most 5 bits is thus obtained.

We claim:

1. A test configuration for a parallel functional testing of semiconductor memory modules, comprising:
a test unit for providing a test sequence;
an interface;
a semiconductor memory module to be tested;
a test logic circuit connected to said test unit via said interface for a bidirectional communication, said test logic circuit being disposed on said semiconductor memory module and receiving the test sequence;
said test unit feeding the test sequence to said semiconductor memory module and said test unit receiving response signals generated by said semiconductor memory module after the test sequence has been run through and said test unit evaluating the response signals; and
said semiconductor memory module having ports for connecting said interface, only one of said ports serving for outputting of data to be read out from said semiconductor memory module.

2. The test configuration according to claim 1, wherein said interface is a serial interface.

3. The test configuration according to claim 1, wherein:
said semiconductor memory module to be tested has at most two ports for connecting said interface;
a first one of said at most two ports serving for inputting and outputting of data of said semiconductor memory module and for inputting of commands; and
a second one of said at most two ports serving for feeding a clock signal.

4. The test configuration according to claim 1, wherein:
said semiconductor memory module to be tested has at most three ports for connecting said interface;
a first one of said at most three ports serving for inputting and outputting of data of said semiconductor memory module;
a second one of said at most three ports serving for inputting of commands; and
a third one of said at most three ports serving for feeding a clock signal.

5. The test configuration according to claim 1, wherein:
said semiconductor memory module to be tested has at most four ports for connecting said interface;
a first one of said at most four ports serving for inputting data;
a second one of said at most four ports serving for outputting data of said semiconductor memory module;
a third one of said at most four ports serving for inputting commands; and
a fourth one of said at most four ports serving for feeding a clock signal.

6. The test configuration according to claim 1, wherein:
a first one of said ports for connecting said interface feeds a clock signal; and
a second one of said ports for connecting said interface feeds a further clock signal.

7. The test configuration according to claim 1, including a time reference device disposed outside said test unit and operatively connected to said semiconductor memory module for providing a time reference to said semiconductor memory module to be tested.

8. The test configuration according to claim 1, wherein said test unit includes a time reference device for providing a time reference to said semiconductor memory module to be tested.

9. The test configuration according to claim 1, wherein said semiconductor memory module is a DRAM module.

10. A method for a parallel functional testing of semiconductor memory modules, the method which comprises:
providing a test unit connected to a test logic circuit via an interface for bidirectional communication and providing a semiconductor memory module having ports for providing a connection to the interface such that only one of the ports serves for outputting of data to be read out from the semiconductor memory module;
providing a test sequence with the test unit and feeding the test sequence via the interface to the semiconductor memory module to be tested;
running the test sequence on the semiconductor memory module to be tested; and
feeding response signals generated by the semiconductor memory module to be tested via the interface to the test unit after the test sequence has been run through and evaluating the response signals.

11. The method according to claim 10, which comprises providing a time reference for the semiconductor memory module to be tested independently of the test unit.

12. The method according to claim 10, which comprises feeding the test sequence to the semiconductor memory module to be tested at a relatively lower transmission rate, and carrying out the test sequence on the semiconductor memory module to be tested at a relatively higher execution speed.
